(19) United States
(12) Patent Application Publication
(10) Pub. No.: US 2022/0307158 A1
(43) Pub. Date: Sep. 29, 2022

(54) NANOPOWDER CONTINUOUS PRODUCTION DEVICE FOR IMPROVING NANOPOWDER COLLECTION EFFICIENCY

(71) Applicant: Tae Yun Kim, Gimhae-si (KR)

(72) Inventor: Tae Yun Kim, Gimhae-si (KR)

(21) Appl. No.: 17/805,350

(22) Filed: Jun. 3, 2022

Related U.S. Application Data
(63) Continuation of application No. PCT/KR2019/017119, filed on Dec. 5, 2019.

(51) Int. Cl. C30B 30/04; C30B 23/00; C30B 35/00

(52) U.S. Cl. CPC C30B 30/04; C30B 23/002; C30B 35/002; B82Y 40/00

(57) ABSTRACT

A nanopowder continuous production device for improving nanopowder collection efficiency is proposed. In one aspect, the device includes a reaction chamber evaporating a raw material using a plasma electrode and a crucible, and a raw material supplier connected to a first side of the reaction chamber and supplying the raw material to the reaction chamber. The device may also include a conveying film moving along a closed loop while capturing and conveying evaporated raw material or crystallized nanopowder at an upper portion in the reaction chamber, and a collector connected to a second side of the reaction chamber and collecting the nanopowder conveyed by the conveying film. The collector may include a first capturer having a scrapper disposed at an end of the conveying film and tensioners elastically supporting the scrapper, and a first side of the scrapper is in close contact with the conveying film.

### CROSS-REFERENCE TO RELATED APPLICATIONS

This application is a continuation application, and claims the benefit under 35 U.S.C. § 120 and § 365 of PCT Application No. PCT/KR2019/017119 filed on Dec. 5, 2019, the contents of which are hereby incorporated by reference in its entirety.

### BACKGROUND

### Technical Field

The present disclosure relates to a nanopowder production device and, more particularly, to a nanopowder continuous production device for improving nanopowder collection efficiency, the device being able to increase productivity of nanopowder by not only continuously producing nanopowder having a uniform grain size, but smoothly collecting the continuously produced nanopowder.

### Description of Related Technology

In general, nanopowder is a material of which the size of 1 dimension is less than 100 nm.

Techniques about nanopowder enable control and manufacturing at the atomic and molecular levels, thereby bringing innovative changes throughout industrial fields including not only a material field, but electric, electronic, bioscientific, chemical, environmental, and energy fields.

### SUMMARY

The present disclosure provides a nanopowder continuous production device for improving nanopowder collection efficiency, the device being able to increase productivity of nanopowder by not only continuously producing nanopowder having a uniform grain size, but smoothly collecting the continuously produced nanopowder.

The present disclosure proposes a nanopowder continuous production device for improving nanopowder collection efficiency. The nanopowder continuous production device includes: a reaction chamber evaporating a raw material using a plasma electrode and a crucible; a raw material supplier connected to a first side of the reaction chamber and supplying the raw material to the reaction chamber; a conveying film moving along a closed loop while capturing and conveying the raw material that has been evaporated or nanopowder that has been crystallized at an upper portion in the reaction chamber; a collector connected to a second side of the reaction chamber and collecting the nanopowder conveyed by the conveying film, in which the collector includes a first capturer having: a scrapper disposed in a width direction at an end of the conveying film; and tensioners elastically supporting an end and another end in a longitudinal direction of the scrapper, and a first side of the scrapper in close contact with the conveying film in the width direction of the conveying film due to elastic supporting by the tensioners.

According to the nanopowder continuous production device for improving nanopowder collection efficiency of the present disclosure, since a raw material is evaporated by thermal plasma that is produced between a crucible electrode and a plasma electrode, nanopowder having a uniform grain size can be continuously produced, so productivity of nanopowder can be increased.

Further, according to the nanopowder continuous production device for improving nanopowder collection efficiency, since the first capturer of the collector includes a scrapper and tensioners and the scrapper is in close contact with the conveying film in a width direction due to elastic supporting by the tensioners, nanopowder is easily separated from the surface of the conveying film by the scrapper, so nanopowder can be smoothly collected. Accordingly, productivity of nanopowder can be more increased.

### BRIEF DESCRIPTION OF THE DRAWINGS

FIG. 1 is a schematic view for describing the structure of a nanopowder continuous production device for improving nanopowder collection efficiency according to the present disclosure.

FIG. 2 is a one-directional perspective view showing the external shape of the nanopowder continuous production device for improving nanopowder collection efficiency according to the present disclosure.

FIG. 3 is an another-directional perspective view showing the external shape of the nanopowder continuous production device for improving nanopowder collection efficiency according to the present disclosure.

FIG. 4 is a cross-sectional view for describing the structure of a nanopowder continuous production device for improving nanopowder collection efficiency according to the present disclosure.

FIG. 5 is a side view of an automatic feeder of the nanopowder continuous production device for improving nanopowder collection efficiency according to the present disclosure.

FIG. 6A, FIG. 6B, and FIG. 6C are detailed views of a crucible in the nanopowder continuous production device for improving nanopowder collection efficiency according to the present disclosure.

FIG. 7 is a detailed view of the crucible and a crucible electrode in the nanopowder continuous production device for improving nanopowder collection efficiency according to the present disclosure.

FIG. 8 is a detailed view of a plasma electrode in the nanopowder continuous production device for improving nanopowder collection efficiency according to the present disclosure.

FIG. 9 is an exemplary view showing modularization of the nanopowder continuous production device for improving nanopowder collection efficiency according to the present disclosure.

FIG. 10 is an internal perspective view for describing the structure of a first capturer of a collector in the nanopowder continuous production device for improving nanopowder collection efficiency according to the present disclosure.

FIG. 11 is a partial cross-sectional view for describing the structure of the first capturer of the collector in the nanopowder continuous production device for improving nanopowder collection efficiency according to the present disclosure.

FIG. 12 is an exemplary view for describing operation of a scrapper of the first capturer of the collector in the nanopowder continuous production device for improving nanopowder collection efficiency according to the present disclosure.

FIG. 13 is an exemplary view for describing close contact of the scrapper of the first capturer of the collector in the nanopowder continuous production device for improving nanopowder collection efficiency according to the present disclosure.

### DETAILED DESCRIPTION

There are a wet-type method, a mechanical crushing method, etc. as a method of producing nanopowder, but the wet-type method has a problem that the process is complicated, productivity is low, and noxious substances are discharged to the environment and the mechanical crushing method has difficulty in producing nanopowder under a predetermined size. Due to these problems, a method of producing nanopowder using plasma is recently used.

Production of nanopowder using thermal plasma uses a principle that when raw particles are put into super-high-temperature thermal plasma at about 10000° C., the raw particles are evaporated completely into an atomic state due to high temperature and the evaporated atoms are nucleated into nanoparticles through cooling. Such a method of producing nanopowder using thermal plasma can be classified into a transferred type and a non-transferred type on the basis of the structure of a torch.

According to the non-transferred type, all electrodes are mounted in a torch and generate arcs therein and the arcs are ejected to the outside by a carrier gas coming out from the rear. Further, according to the transferred type, a cathode and an anode are spaced with a predetermined gap and the length of an arc is adjusted by adjusting the gap.

An apparatus for producing nanopowder using thermal plasma has been disclosed in Korean Patent No. 10-0788412. The registered patent includes a power supplier, a plasma torch, a reaction chamber, a vacuum pump, a cooling tube, a capturer, and a scrubber, in which a specimen evaporated by plasma in the reaction chamber is crystallized into nanopowder through the cooling tube and then captured by the capturer.

However, when this structure is used, there is a problem that it is difficult to continuously supply a raw material, and particularly, the process of collecting nanopowder is complicated, so productivity of nanopowder decreases.

Hereinafter, the present disclosure is described in detail on the basis of the accompanying drawings.

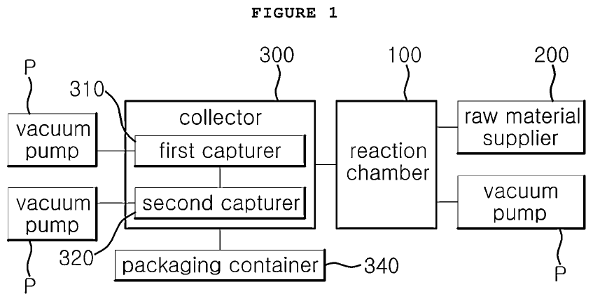

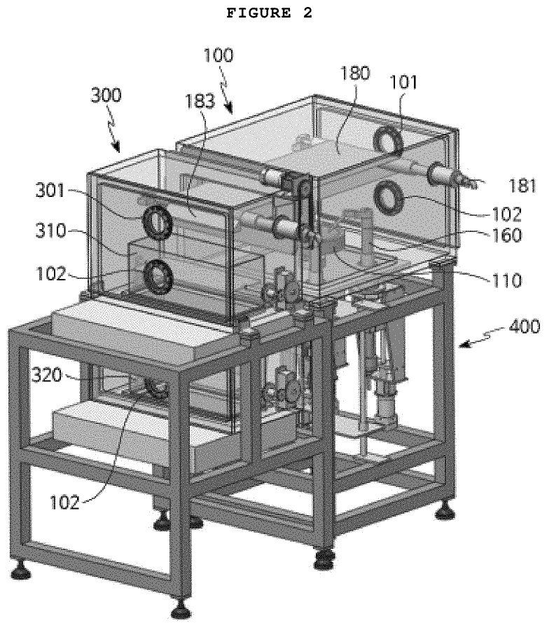

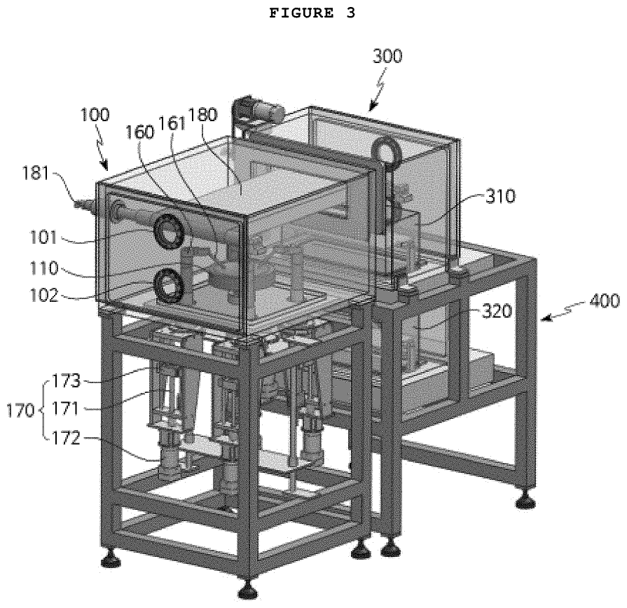

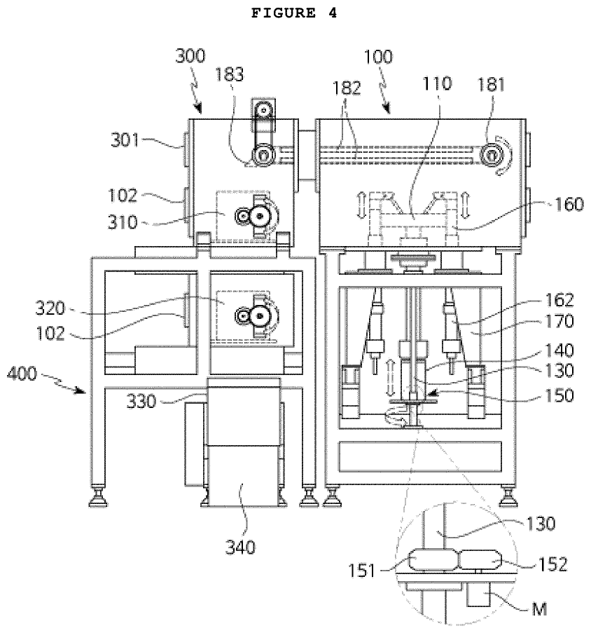

As shown in FIGS. 1 to 4, a nanopowder continuous production device A for improving nanopowder collection efficiency according to the present disclosure includes: a reaction chamber 100; a raw material supplier 200, a conveying film 180, and a collector 300.

The reaction chamber 100 of the present disclosure evaporates a raw material using a plasma electrode 160 and a crucible 110.

The reaction chamber 100 has the plasma electrode 160, the crucible 110, and the conveying film 180, is connected on a first side with the raw material supplier 200 that is supplied with a raw material and on a second side with the collector 300 that collects a nanomaterial.

Further, a support frame 400 is disposed under the reaction chamber 100 and the bottom of the reaction chamber 100 is supported by the support frame 400, whereby the reaction chamber 100 is positioned at a set height.

In this case, the support frame 400 supports not only the reaction chamber 100, but the collector 300 and the raw material supplier 200 at set heights, respectively.

Further, the reaction chamber 100 has a substance supply port 101 connected with the raw material supplier 200 and a vacuum port 102 connected with a vacuum pump P, etc., on at least any one side.

In this case, the reaction chamber 100, and the collector 300 and the raw material supplier 200 that are connected to the reaction chamber 100 may be maintained in a vacuum state.

Further, the crucible 110 and the plasma electrode 160 are disposed with a predetermined distance therebetween in the reaction chamber 100 and plasma produced by the plasma electrode 160 generates an arc toward the crucible 110.

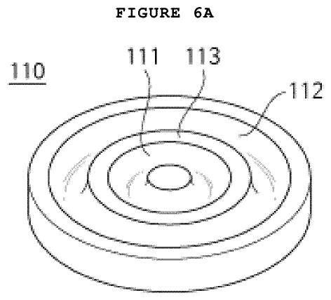

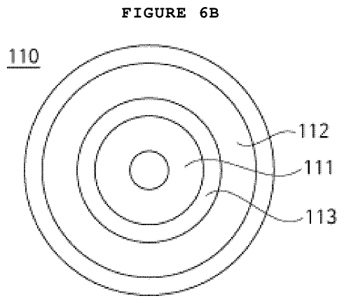

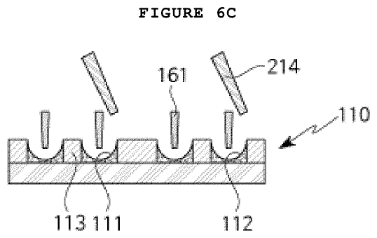

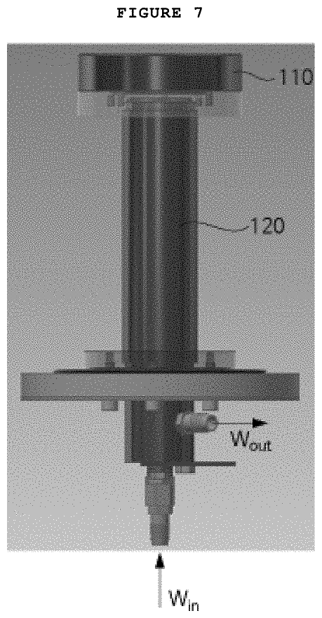

Further, the crucible 110 in the reaction chamber 100, as shown in FIGS. 6A-6C and 7, is connected with a crucible electrode 120 and may be made of graphite so that the crucible 100 can resist a high-temperature atmosphere and electricity can be conducted.

The crucible electrode 120 is connected to the center of the bottom of the crucible 110 and cooling water may be separately supplied into and discharged from the crucible electrode 120.

In this case, a crucible center shaft 130 is connected to the bottom of the crucible electrode 120.

Further, the crucible 110 may have a dual structure.

In more detail, the crucible 110 may include: a first track 111 recessed downward; a second track 112 having an inner circumference larger than the outer circumference of the first track 111 and recessed downward; and an isolation projection 113 disposed between the first track 111 and the second track 112 and isolating the first track 111 and the second track 112 from each other.

In this case, a raw material supplied from the automatic feeder 210, which will be described below, may be received in the first track 111 and the second track 112, and a plurality of plasma electrodes 160 may be provided to be fitted to the first track 111 and the second track 112, for example, four plasma electrodes 160 may be provided for the first track 111 and the second track 112.

In this case, the number and positions of plasma electrodes 160 may be determined in consideration of the circumferences of the first track 111 and the second track 112.

Further, a raw material of the same substance or raw materials of different substances may be supplied to the first track 111 and the second track 112, respectively.

In this case, a plurality of automatic feeders 210 to be described below is provided and supplies raw materials to the first track 111 and the second track 112, respectively.

That is, automatic feeders 210 to be described below supply a raw material of the same substance or raw materials of different substances to the first track 111 and the second track 112 though feeding nozzles 214, respectively.

The crucible 110 having a dual structure, as described above, can effectively adjust an evaporation amount and an evaporation speed due to the differences in position and temperature of the first track 111 and the second track 112 when a raw material of the same substance is supplied, and can compound raw materials of different substances in a gas state when raw materials of different substances are supplied, whereby complex nanopowder can be produced.

Further, the plasma electrode 160 is disposed at a predetermined distance from the crucible 110 and forms a hot cathode in the reaction chamber 100.

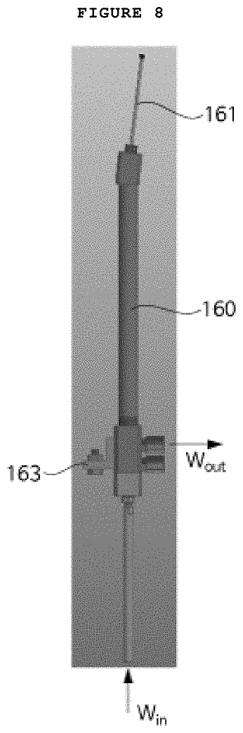

In this case, as shown in FIG. 8, a tip 161 made of tungsten or graphite may be fastened to an end of the plasma electrode 160 and cooling water may be separately supplied into and discharged from the lower portion of the plasma electrode 160.

Further, the plasma electrode 160 may have an electrode center shaft 162 vertically extending and a connection terminal 163, which is connected with a power source, on a side of the electrode center shaft 162.

In this case, cooling water can flow into the electrode center shaft 162.

Meanwhile, the reaction chamber 100 includes: a crucible height adjuster 140 that adjusts the height of the crucible 110; a rotator 150 that rotates the crucible 110; and an electrode height adjuster 170 that adjusts the height of the plasma electrode 160.

In this case, the crucible height adjuster 140 includes: a first screw shaft 143 (not shown) that vertically extends; a first screw motor 144 (not shown) that rotates the first screw shaft 143; and a first ball nut 145 that is fastened to the first screw shaft 143 and reciprocates up and down with rotation of the first screw shaft 143. The crucible center shaft 130 connected to the crucible 110 is connected to the first ball nut 145 that is moved up and down by rotation of the first screw shaft 143, whereby the crucible center shaft 130 is moved up and down by upward and downward movement of the first ball nut 145 and the crucible 110 connected to the crucible center shaft 130 is moved up and down by upward and downward movement of the crucible center shaft 130.

Accordingly, the gap between a raw material in the crucible 110 and the plasma electrode 160 is increased or decreased by moving up or down the crucible 110, whereby the evaporation amount and the evaporation speed of the raw material are adjusted in the process of evaporation of the raw material.

The crucible rotator 150 includes: a first gear 151 that is coupled and fixed to the lower end portion of the crucible center shaft 130 extending downward from the crucible 110; and a second gear 152 that is rotated by operation a motor and is in mesh with the first gear 151. When the second gear 152 is rotated by operation of the motor, the crucible center shaft 130 is rotated, so the crucible 110 is rotated clockwise or counterclockwise.

Accordingly, the gap between a raw material in the crucible 110 and the plasma electrode 160 is increased or decreased by rotating the crucible 110, whereby the evaporation amount and the evaporation speed of the raw material are adjusted in the process of evaporation of the raw material.

The electrode height adjuster 170 includes: a second screw shaft 171 that is coupled the support frame 400, vertically extends, and is rotated by operation of the second screw motor 172; and a second ball nut 173 that is fastened to the second screw shaft 171 and is moved up and down by rotation of the second screw shaft 171. Since the electrode center shaft 162 is connected to the second ball nut 173, the plasma electrode 160 connected with the electrode center shaft 162 is moved up and down by upward and downward movement of the second ball nut 173.

Accordingly, the gap between a raw material in the crucible 110 and the plasma electrode 160 is increased or decreased by moving up or down the plasma electrode 160, whereby the evaporation amount and the evaporation speed of the raw material are adjusted in the process of evaporation of the raw material.

The structures of the second screw shaft 171, the second strew motor 172, and the second ball nut 173 may be the same as the first screw shaft 143, the first screw motor 172, and the second ball nut 145 described above.

The raw material supplier 200 of the present disclosure is connected to a side of the reach chamber 100 and supplies a raw material into the reaction chamber 100.

In this case, a raw material is changed into nanopowder through evaporation and condensation in the reaction chamber 100, and the changed nanopowder is collected into the collector 300.

The raw material supplier 200 may include an automatic feeder 210 that supplies a raw material into the reaction chamber 100.

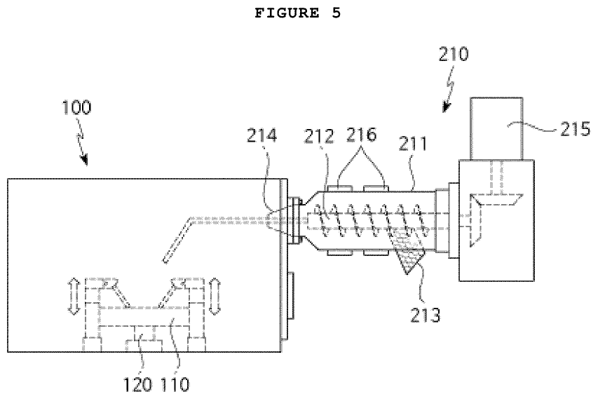

The automatic feeder 210, as shown in FIG. 5, includes: a feeding housing 211; a feeding screw 212 spirally disposed in the feeding housing 211; a feeding motor 215 operating the feeding screw 212; and a feeding nozzle 214 connected to the feeding housing 211 and supplying a raw material into the reaction chamber 100, whereby a raw material can be transferred in a extrusion type by rotation of the feeding screw 212 with the inside of the feeding housing 211 in a vacuum state.

In this case, the feeding housing 211 has a cylindrical sealed structure and maintains the inside in a vacuum state, the feeding nozzle 214 may be connected to a side of the feeding housing 211, and the feeding motor 215 may be connected to another side thereof.

Further, the feeding housing 211 may be connected to the first side of the reaction chamber 100 so that the feeding nozzle 214 smoothly supplies a raw material to the crucible 110 disposed in the reaction chamber 100.

Further, the feeding housing 211 has an opening-closing unit 213 through which a raw material is supplied.

In this case, a load lock type valve may be used as the opening-closing unit 213 to minimize influence on the internal vacuum environment of the feeding housing 211.

In this case, a raw material supplied inside through the opening-closing unit 213 is transferred toward the feeding nozzle 214 by rotation of the feeding screw 212, so a raw material can be continuously supplied to the crucible 110 disposed in the reaction chamber 100 through the feeding nozzle 214.

Further, a feeding heater 216 that heats a raw material in the feeding housing 211 up to a set temperature may be connected to the outer side of the feeding housing 211, and a plurality of feeding heaters 216 may be provided.

A side of the feeding housing 211 is coupled to the substance supply port 101, and in this case, the feeding nozzle 214 connected to the feeding hosing 211 is positioned in the reaction chamber 100.

The shape and structure of the feeding nozzle 214 may be various and a plurality of feeding nozzles 214 may be provided.

The conveying film 180 of the present disclosure captures and conveys an evaporated raw material or crystallized nanopowder at the upper portion in the reaction chamber 100 along a closed loop.

The conveying film 180 is disposed at a predetermined distance from the crucible 110 and is partially or entirely positioned at the upper portion in the reaction chamber 100.

In this case, the conveying film 180 is made of metal and can capture an evaporated raw material on the surface thereof using an electrical or magnetic property.

Further, each of both sides of the conveying film 180 is supported by a conveying shaft 181 that is horizontally elongated.

In this case, cooling water may be supplied into the conveying shaft 181.

The conveying shaft 181 may be disposed horizontally through the reaction chamber 100 or the collector 300 so that cooling water is easily supplied and discharged.

Meanwhile, the conveying film 180 extends from the reaction chamber 100 to the collector 300, thereby conveying a raw material captured in the reaction chamber 100 to the collector 300.

That is, the conveying film 180 moves into the collector 300 from the inside of the reaction chamber 100 while moving on a continuous track along a closed loop.

In this case, the conveying film 180 or the conveying shaft 181 may be rotated by operation of a motor disposed outside the reaction chamber 100 or the collector 300.

Further, the conveying film 180 may further include a cooling plate 182.

The cooling plate 182 may be in contact with the inner side of the conveying film and cools the conveying film 180 to a set temperature.

In this case, an evaporated raw material captured on the outer side of the conveying film 180 is cooled to a set temperature by the cooling plate 182 and is condensed while being moved toward the collector 300 from the reaction chamber 100, whereby the evaporated raw material can be crystallized into nanopowder.

Cooling of the conveying film 180 through the cooling plate 182 may be performed using cooling water or inertia gas at a set temperature.

The collector 300 of the present disclosure is connected to the second side of the reaction chamber 100 and collects nanopowder conveyed by the conveying film 180.

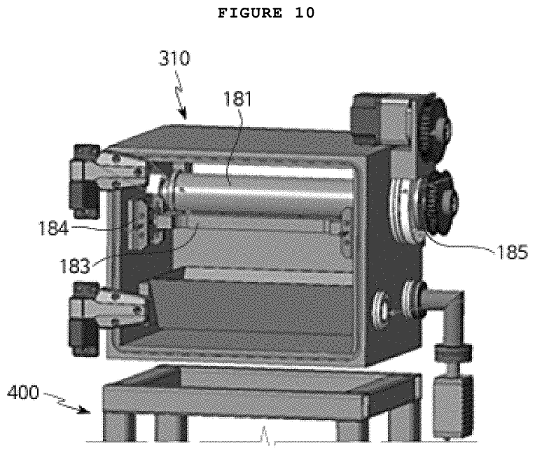

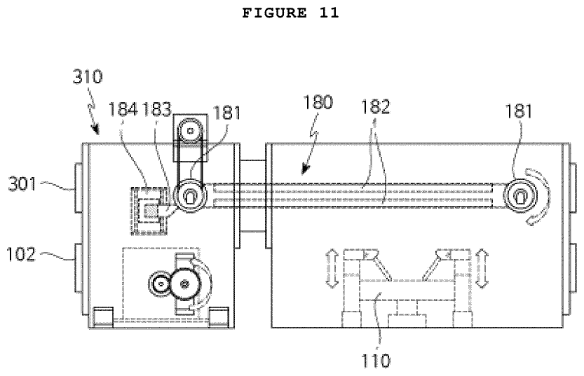

In this case, the collector 300, as shown in FIGS. 10 and 11, includes a first capturer 310 having: a scrapper 183 disposed in a width direction at an end of the conveying film 180; and tensioners 184 elastically supporting an end and another end in a longitudinal direction of the scrapper 183.

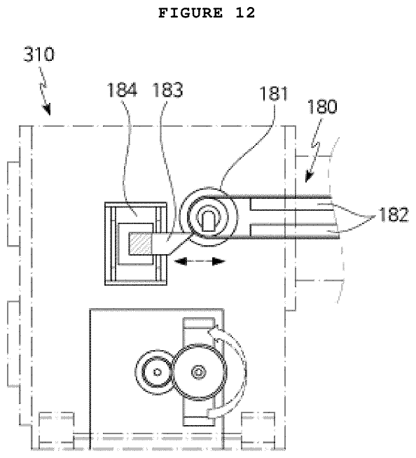

Accordingly, a first side of the scrapper 183 is in close contact with the conveying film 180 in the width direction of the conveying film 180 due to elastic supporting by the tensioners 184, as shown in FIG. 12, so nanopowder is easily separated from the surface of the conveying film 180 by the scrapper 183, and accordingly, nanopowder can be smoothly collected.

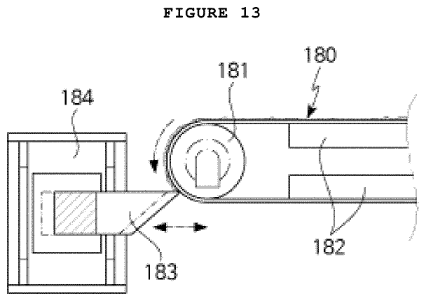

That is, as shown in FIG. 13, the tensioners 184 keeps pushing the scrapper 183 toward the conveying film 180, so the first side of the scrapper 183 is in close contact with the conveying film 180 in the width direction of the conveying film 180, so nanopowder is easily separated from the surface of the conveying film 180 by the scrapper 183 and is smoothly collected. Accordingly, the collection efficiency of nanopowder is improved, and as a result, productivity of nanopowder is improved.

In this case, the tensioners 184 may have any common structure and type as long as they can elastically support the scrapper 183, so the tensioners 184 are not described in detail.

Further, the first capturer 310 may further have magnetic fluid seals 185 disposed at both ends of the conveying shaft 181 of the conveying film 180, respectively.

The magnetic fluid seals 185 prevent fluid, in more detail, an evaporated raw material or nanopowder from leaking through the joints at both ends of the conveying shaft 181, whereby the collection efficiency of nanopowder in the first capturer 310 is further improved.

The first capturer 310 has a vacuum port 102 to which a vacuum pump P, or the like is connected, and nanopowder is moved downward in the first capturer 310 of which the inside is in a vacuum state.

Further, the first capturer 310 may have a load lock valve or a gate valve and may further have various components for capturing and moving nanopowder while maintaining the vacuum state.

Further, the collector 300 includes: a second capturer 320 connected with the first capturer 310 and capturing and transferring nanopowder captured through the first capturer 310; and a powder receiver 330 receiving nanopowder moved through the second capturer 320.

Accordingly, nanopowder that has passed through the first capturer 310 and the second capturer 320 is finally received in the powder receiver 330.

In this case, the powder receiver 330 may be connected with a packaging container and a load lock valve is provided, so nanopowder is moved into the packaging container by a predetermined amount in a vacuum state.

Further, the powder receiver 330 may have a screw conveyer and the screw conveyer moves nanopowder to a predetermined position through spiral screw rotation.

Meanwhile, the first capturer 310 and the second capturer 320 have vacuum ports 120 to which vacuum pumps P, etc. are connected, so the insides thereof are maintained in a vacuum state.

The first capturer 310 and the second capturer 320 may have independently vacuum environments and the internal pressures may be different.

Further, the collector 300 has a view port 301 made of a transparent material at the upper portion, so it is possible to visually check the situation in the collector 300.

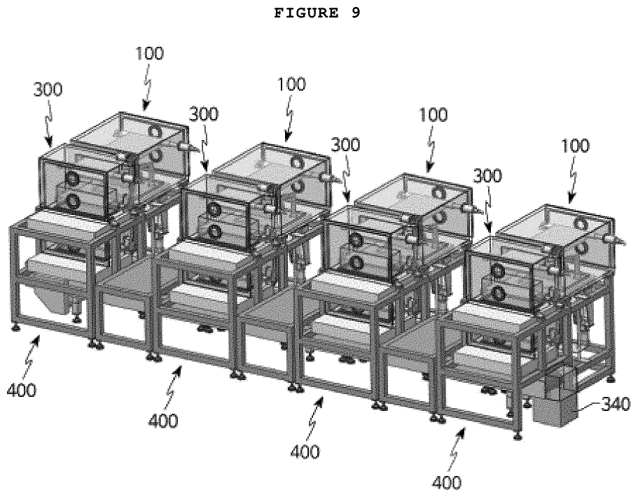

Meanwhile, a plurality of nanopowder continuous production devices A for improving nanopowder collection efficiency according to the present disclosure, as shown in FIG. 9, may be connected in parallel and operated as one module.

When the nanopowder continuous production devices A for improving nanopowder collection efficiency according to the present disclosure are operated in a module, efficiency of making vacuum through a vacuum pump, supplying a raw material through the automatic feeder 210, cooling through cooling water, etc. can be increased, so productivity of nanopowder can be increased.

The nanopowder continuous production device A for improving nanopowder collection efficiency according to the present disclosure described above includes the automatic feeder 210 and the conveying film 180, a raw material is continuously supplied, nanopowder is continuously captured, so nanopowder can be continuously produced.

Further, in the nanopowder continuous production device A for improving nanopowder collection efficiency according to the present disclosure, the raw material supplier 200, the reaction chamber 100, and the collector 300 each have a vacuum port 102 and are all connected with vacuum pumps P, and a raw material is supplied and nanopowder is produced and collected in a vacuum environment, whereby it is possible to prevent surface oxidation of nanopowder due to exposure to the atmosphere.

Further, in the nanopowder continuous production device A for improving nanopowder collection efficiency according to the present disclosure, the first capturer 310 of the collector 300 includes: the scrapper 183 disposed in a width direction at an end of the conveying film 180; and tensioners 184 elastically supporting an end and another end in a longitudinal direction of the scrapper 183, and the first side of the scrapper 183 is in close contact with the conveying film 180 in the width direction of the conveying film 180 due to elastic supporting by the tensioners 184. Accordingly, nanopowder is easily separated from the surface of the conveying film 180 when coming into contact with the scrapper 183, so nanopowder can be smoothly collected and the collection efficiency of nanopowder can be increased.

According to the present disclosure, not only productivity of nanopowder can be increased because nanopowder having a uniform grain size is continuously produced, but the quality of nanopowder can be increased because evaporation of a raw material is optimized. Therefore, the present disclosure has industrial applicability in the field of nanopowder production.

Since the present disclosure described above is not limited to the embodiment described above, the present disclosure may be changed without departing from the spirit described in following claims and such change is included in the protection range of the present disclosure defined in the claims.

What is claimed is:

1. A nanopowder continuous production device for improving nanopowder collection efficiency, the nanopowder continuous production device comprising:
a reaction chamber configured to evaporate a raw material using a plasma electrode and a crucible;
a raw material supplier connected to a first side of the reaction chamber and configured to supply the raw material to the reaction chamber;
a conveying film configured to move along a closed loop while capturing and conveying the raw material that has been evaporated or nanopowder that has been crystallized at an upper portion in the reaction chamber; and
a collector connected to a second side of the reaction chamber and configured to collect the nanopowder conveyed by the conveying film,
wherein the collector includes a first capturer including:
a scrapper disposed in a width direction at an end of the conveying film; and
tensioners configured to elastically support an end and another end in a longitudinal direction of the scrapper, and
wherein a first side of the scrapper is in close contact with the conveying film in the width direction of the conveying film due to elastic supporting by the tensioners.

2. The nanopowder continuous production device of claim 1, wherein the first capturer further includes magnetic fluid seals respectively disposed at both ends of a conveying shaft, horizontally supporting both ends of the conveying film, and preventing the raw material or the nanopowder from leaking through joints at both ends of the conveying shaft.

3. The nanopowder continuous production device of claim 1, wherein the collector includes:
a second capturer connected with the first capturer and configured to capture and transfer the nanopowder captured through the first capturer; and
a powder receiver configured to receive the nanopowder transferred through the second capturer.

4. The nanopowder continuous production device of claim 1, wherein the plasma electrode includes:
a tip fastened to a longitudinal front end adjacent to the crucible and made of tungsten or graphite;
an electrode center shaft vertically extending from another longitudinal end; and
a connection port disposed on a side of the electrode center shaft and connected with a power source.

5. The nanopowder continuous production device of claim 1, wherein the crucible includes:
a first track recessed downward;
a second track including an inner circumference larger than an outer circumference of the first track and recessed downward; and
an isolation projection disposed between the first track and the second track and configured to isolate the first track and the second track from each other.

6. The nanopowder continuous production device of claim 1, wherein the raw material supplier includes an automatic feeder including:
a feeding housing;
a feeding screw spirally disposed in the feeding housing;
a feeding motor configured to operate the feeding screw; and
a feeding nozzle connected to the feeding housing and configured to supply the raw material into the reaction chamber.

7. The nanopowder continuous production device of claim 6, wherein the automatic feeder comprises a plurality of automatic feeders and is configured to supply the raw material of the same substance or the raw material of different substances to a first track and a second track of the crucible.

8. The nanopowder continuous production device of claim 2, wherein cooling water is configured to flow into the conveying shaft.
